(19) United States
(12) Patent Application Publication
(10) Pub. No.: US 2025/0145048 A1
(43) Pub. Date: May 8, 2025

(54) SYSTEM FOR ESTIMATING BATTERY POWER CAPABILITY

(71) Applicant: FORD GLOBAL TECHNOLOGIES, LLC, Dearborn, MI (US)

(72) Inventors: Yonghua LI, Ann Arbor, MI (US); Xiaohong Nina DUAN, Canton, MI (US); Hao WU, Northville, MI (US); Richard Dyche ANDERSON, Plymouth, MI (US); Matthew Allen TOMAI, Livonia, MI (US); Hesam ZOMORODI MOGHADAM, Ypsilanti, MI (US); Justin T. HUGHES, Allen Park, MI (US); Yan WANG, Ann Arbor, MI (US); Michael David BEENEY, Canton, MI (US)

(21) Appl. No.: 18/386,422

(22) Filed: Nov. 2, 2023

(51) Int. Cl. B60L 58/12; G01R 31/3842; G01R 31/396; H02J 7/00

(52) U.S. Cl. CPC B60L 58/12; G01R 31/3842; G01R 31/396; H02J 7/00712; H02J 7/007194; B60L 2240/545

(57) ABSTRACT

One or more controllers, after activation of a vehicle, may charge and discharge a traction battery according to power limits that are based on polarization voltages describing internal states of the traction battery and that are a function of polarization voltages present at a last deactivation of the vehicle and decay values having time constants that are based on a state of charge of the traction battery and a temperature associated with the traction battery.

### TECHNICAL FIELD

The present disclosure relates to a vehicle system for estimating a power capability of a vehicle battery and operating the vehicle according to the power capability.

### BACKGROUND

Electric vehicles (EVs) rely on one or more traction batteries to supply electric energy to a motor for propulsion. The driving operations of the vehicles may depend on the power capability of the traction battery. The power capability may be affected by various factors such as battery temperature, voltage, state of charge (SOC) or the like.

### SUMMARY

A power system for a vehicle includes one or more controllers that, after activation of the vehicle, charge and discharge a traction battery according to power limits that are based on polarization voltages describing internal states of the traction battery and that are a function of polarization voltages present at a last deactivation of the vehicle and decay values having time constants that are based on a state of charge of the traction battery and a temperature associated with the traction battery.

A method includes, after activation of a vehicle, charging and discharging a traction battery of the vehicle according to power limits that are based on polarization voltages describing internal states of the traction battery and that are a function of polarization voltages present at a last deactivation of the vehicle and decay values having time constants that are based on a state of charge of the traction battery and a temperature associated with the traction battery.

A vehicle includes a traction battery and one or more controllers that, after activation of the vehicle, charge and discharge the traction battery according to power limits. The power limits are derived from polarization voltages that are based on decay values having time constants that are based on a state of charge of the traction battery and a temperature associated with the traction battery.

### BRIEF DESCRIPTION OF THE DRAWINGS

FIG. 1 illustrates an example block topology of an electrified vehicle illustrating drivetrain and energy storage components.

FIG. 2 illustrates a block diagram of an arrangement for a traction battery controller of a battery electric vehicle (BEV) to monitor a traction battery of the BEV;

FIG. 3 illustrates a schematic diagram of a conventional equivalent circuit model (ECM) of the traction battery; and

FIG. 4 illustrates a timing graph of a process for estimating a power capability of a vehicle battery.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes a system and method for estimating a power capability of a vehicle traction battery when the vehicle is started, and operating the vehicle based on the power capability.

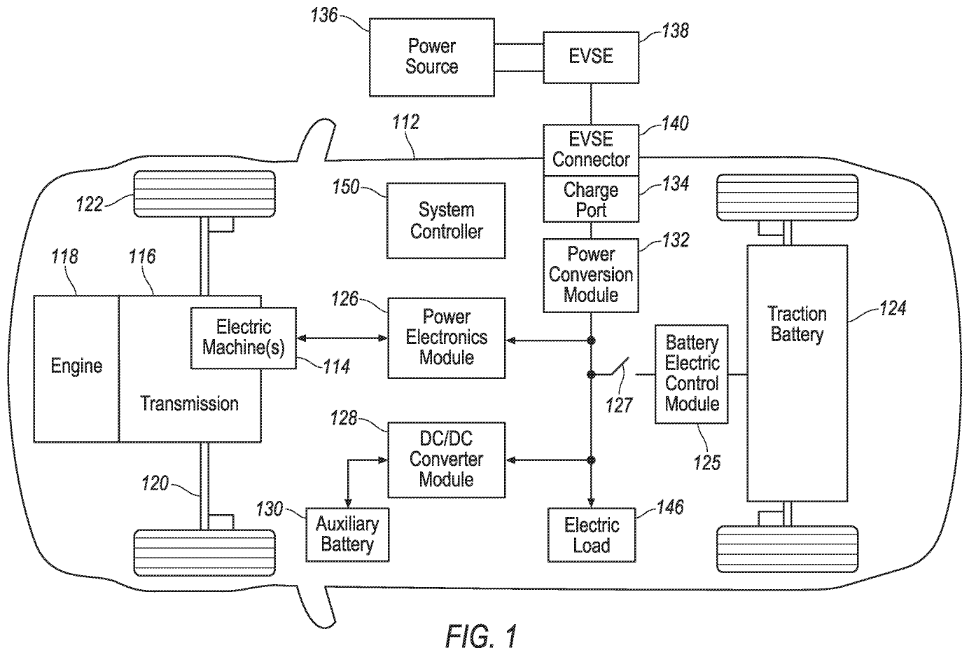

FIG. 1 illustrates a plug-in hybrid-electric vehicle (PHEV). A plug-in hybrid-electric vehicle 112 may comprise one or more electric machines (electric motors) 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to the wheels 122. The electric machines 114 may provide propulsion and deceleration capability when the engine 118 is turned on or off. The electric machines 114 may also act as generators and may provide fuel economy benefits by recovering energy that would be lost as heat in the friction braking system. The electric machines 114 may also reduce vehicle emissions by allowing the engine 118 to operate at more efficient speeds and allowing the hybrid-electric vehicle 112 to be operated in electric mode with the engine 118 off under certain conditions.

A traction battery or battery pack 124 stores energy that may be used by the electric machines 114. A vehicle battery pack 124 may provide a high voltage DC output. The traction battery 124 may be electrically coupled to one or more battery electric control modules (BECM) 125. The BECM 125 may be provided with one or more processors and software applications configured to monitor and control various operations of the traction battery 124. The traction battery 124 may be further electrically coupled to one or more power electronics modules 126. The power electronics module 126 may also be referred to as a power inverter. One or more contactors 127 may isolate the traction battery 124 and the BECM 125 from other components when opened and couple the traction battery 124 and the BECM 125 to other components when closed. The power electronics module 126 may also be electrically coupled to the electric machines 114 and provide the ability to bi-directionally transfer energy between the traction battery 124 and the electric machines 114. For example, a traction battery 124 may provide a DC voltage while the electric machines 114 may operate using a three-phase AC current. The power electronics module 126 may convert the DC voltage to a three-phase AC current for use by the electric machines 114. In a regenerative mode, the power electronics module 126 may convert the three-phase AC current from the electric machines 114 acting as generators to the DC voltage compatible with the traction battery 124. The description herein is equally applicable to a pure electric vehicle. For a pure electric vehicle, the hybrid transmission 116 may be a gear box connected to the electric machine 114 and the engine 118 may not be present.

In addition to providing energy for propulsion, the traction battery 124 may provide energy for other vehicle electrical systems. A vehicle may include a DC/DC converter module 128 that converts the high voltage DC output of the traction battery 124 to a low voltage DC supply that is compatible with other low-voltage vehicle loads. An output of the DC/DC converter module 128 may be electrically coupled to an auxiliary battery 130 (e.g., 12V battery).

The vehicle 112 may be a battery electric vehicle (BEV) or a plug-in hybrid electric vehicle (PHEV) in which the traction battery 124 may be recharged by an external power source 136. The external power source 136 may be a connection to an electrical outlet. The external power source 136 may be an electrical power distribution network or grid as provided by an electric utility company. The external power source 136 may be electrically coupled to electric vehicle supply equipment (EVSE) 138. The EVSE 138 may provide circuitry and controls to regulate and manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EVSE connector 140 may have pins that mate with corresponding recesses of the charge port 134. Alternatively, various components described as being electrically coupled may transfer power using a wireless inductive coupling. Although the vehicle 112 is illustrated as a BEV or PHEV with reference to FIG. 1, the present disclosure is not limited thereto. The vehicle 112 may also be a hybrid electric vehicle (HEV) or a fuel cell electric vehicle (FCEV) under essentially the same concept.

One or more electrical loads 146 may be coupled to the high-voltage bus. The electrical loads 146 may have an associated controller that operates and controls the electrical loads 146 when appropriate. Examples of electrical loads 146 may be a heating module, an air-conditioning module, or the like.

The various components discussed may have one or more associated controllers to control and monitor the operation of the components. The controllers may communicate via a serial bus (e.g., Controller Area Network (CAN)) or via discrete conductors. A system controller 150 may be present to coordinate the operation of the various components. It is noted that the system controller 150 is used as a general term and may include one or more controller devices configured to perform various operations in the present disclosure. For instance, the system controller 150 may be programmed to enable a powertrain control function to operate the powertrain of the vehicle 112. The system controller 150 may be further programmed to enable a telecommunication function with various entities (e.g. a server) via a wireless network (e.g. a cellular network).

The system controller 150 and/or the BECM 125, individually or combined, may be programmed to perform various operations with regard to the traction battery 124. The traction battery 124 may be a rechargeable battery made of one or more rechargeable cells (e.g. lithium-ion cells). For instance, the BECM 125 may be a traction battery controller operable for managing the charging and discharging of the traction battery 124 and for monitoring operating characteristics of the traction battery 124. The BECM 125 may be operable to implement algorithms to measure (e.g., detect or estimate) the operating characteristics of the traction battery 124. The BECM 125 may control the operation and performance of the traction battery 124 based on the operating characteristics. The operation and performance of other systems and components of the vehicle 112 may be controlled based on the operating characteristics of the traction battery 124.

Operating characteristics of the traction battery 124 include the charge capacity and the state-of-charge (SOC) of the traction battery 124. The charge capacity of the traction battery 124 is indicative of the maximum amount of electrical energy that the traction battery may store. The SOC of the traction battery 124 is indicative of a present amount of electrical charge stored in the traction battery. The SOC of the traction battery 124 may be represented as a percentage of the maximum amount of electrical charge that may be stored in the traction battery 124.

Another operating characteristic of the traction battery 124 is the power capability of the traction battery. The power capability of the traction battery 124 is a measure of the maximum amount of power the traction battery can provide (i.e., discharge) or receive (i.e., charge) for a specified time period. As such, the power capability of the traction battery 124 corresponds to discharge and charge power limits which define the amount of electrical power that may be supplied from or received by the traction battery 124 at a given time. These limits can be provided to other vehicle controls, for example, through the system controller 150, so that the information can be used by systems that may draw power from or provide power to the traction battery 124. Vehicle controls need to know how much power The traction battery 124 can provide (discharge) or receive (charge) in order to meet the driver's driving demand and HVAC (Heating, Ventilation and Air Conditioning) demand and to optimize the energy usage. As such, knowing the power capability of the traction battery 124 allows electrical loads and sources to be managed such that the power requested is within the allowed voltage and current limits that the traction battery can handle.

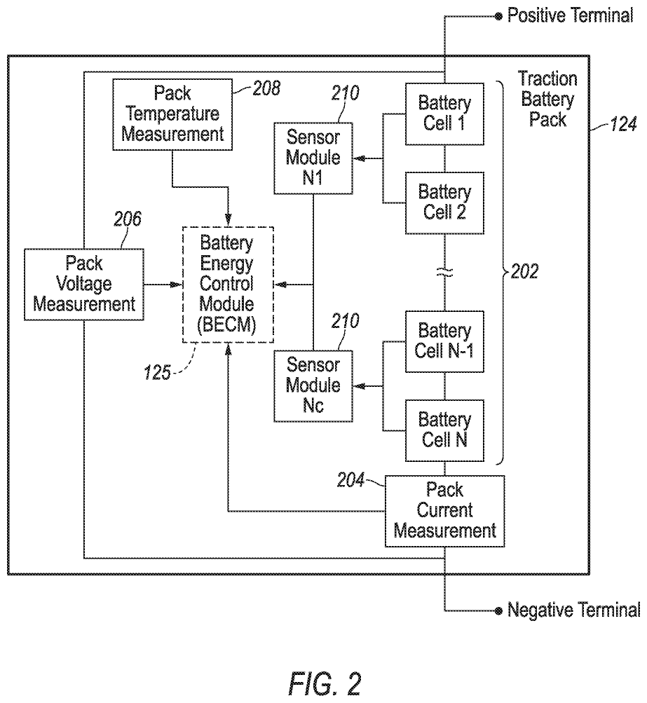

Referring to FIG. 2, with continuing reference to FIG. 1, a block diagram of an arrangement for the BECM 125 to monitor the traction battery 124 is illustrated. In the present example, the BECM 125 may be integrated with the traction battery 124 although the present disclosure is not limited thereto. The traction battery 124 includes a plurality of battery cells 202. The battery cells 202 may be physically connected together (e.g., connected in series as illustrated in FIG. 2).

The BECM 125 may be operable to monitor pack level characteristics of the traction battery 124 such as battery current 204, battery pack voltage 206, and battery temperature 208. The battery current 204 is the current output (i.e., discharged) from or input (i.e., charged) to the traction battery 124. The battery pack voltage 206 is the terminal voltage of the traction battery 124.

The BECM 125 may also be operable to measure and monitor battery cell level characteristics of battery cells 202 of the traction battery 124. For example, terminal voltage, current, and temperature of one or more of battery cells 202 may be measured. The BECM 125 may use one or more battery sensors 210 to measure the battery cell level characteristics. The battery sensors 210 may measure the characteristics of one or multiple battery cells 202. The BECM 125 may utilize an Nc number of battery sensors 210 to measure the characteristics of all battery cells 202. Each battery sensor 210 may transfer the measurements to the BECM 125 for further processing and coordination. In one embodiment, the battery sensors 210 functionality may be incorporated internally to the BECM 125.

The traction battery 124 may have one or more temperature sensors such as thermistors in communication with the BECM 125 to provide data indicative of the temperature of battery cells 202 of the traction battery 124 for the BECM to monitor the temperature of the traction battery and/or the battery cells. The vehicle 112 may further include one or more temperature sensors 208 to provide data indicative of ambient temperature for the BECM 125 to monitor the ambient temperature.

The BECM 125 may control the operation and performance of the traction battery 124 based on the monitored traction battery and battery cell level characteristics. For instance, the BECM 125 may use the monitored characteristics to measure (e.g., detect or estimate) operating characteristics of the traction battery 124 (e.g., the power capability of the traction battery, the SOC of the traction battery, and the like) such as for use in controlling the traction battery and/or vehicle 112.

As known by those of ordinary skill in the art, the BECM 125 may estimate values of parameters of the ECM (e.g., resistances and capacitances of circuit elements of the ECM) and values of states of the ECM (e.g., voltages and currents across circuit elements of the ECM) through recursive estimation based on such measurements. For instance, the BECM 125 may use some adaptive estimation method, such as extended Kalman filter (EKF), to estimate the values of the model parameters and model states.

For the values of the operating characteristics of the traction battery 124 measured by the BECM 125 to be accurate with the actual values of the operating characteristics of the traction battery, the ECM has to accurately model the traction battery. For the ECM to accurately model the traction battery 124, (i) the ECM has to have an adequate set of parameters (e.g., resistances and capacitances of circuit elements of the ECM) and (ii) the estimated values of the model parameters and model states have to be at least substantially similar to the values of the parameters and the states of an ECM that accurately model the traction battery (i.e., the estimated parameter and state values have to be at least substantially similar to the actual parameter and state values).

As set forth, an accurate model of the traction battery 124 enables the BECM 125 to properly control the traction battery which directly affects vehicle performance and driving range for a given full charge. ECMs are widely used in electrified vehicle traction battery control systems in order to satisfy real time control system requirements for calculation speed and RAM/ROM usage. Particularly, an n-RC ECM where n=1 or 2 is widely used (an n-RC ECM is a type of ECM having “n” RC circuit elements each including a resistor (“R”) parameter and a capacitor (“C”) parameter; with n=1, a 1-RC ECM includes one such RC circuit element; and with n=2, a 2-RC ECM includes two such RC circuit elements). As indicated, the parameters for the ECM are learned with an online learning method such as Kalman Filter or Extended Kalman Filter (EKF).

In accordance with the present disclosure, the BECM 125 employs an equivalent circuit model of the traction battery 124 that efficiently represents complex battery dynamics of the traction battery. The number of parameters of the proposed ECM are less than the number of parameters of multi-RC pair ECMs having three or more RC circuit elements, and the parameters of the proposed ECM can be learned using EKF or similar methods under reasonable BECM capabilities such as CPU utilization ratio and RAM/ROM availability.

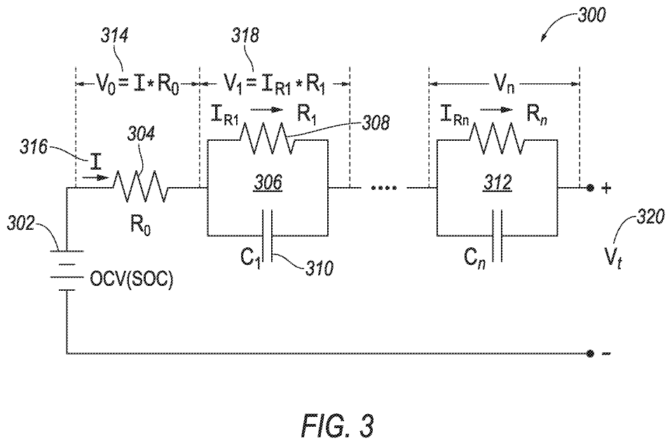

Referring now to FIG. 3, with continuing reference to FIGS. 1 and 2, a schematic diagram of an ECM 300 of the traction battery 124 is shown. Per the ECM 300, the traction battery 124 is modeled as a circuit having in series a voltage source (OCV/(SOC)) 302, a resistor R₀ 304, a first RC pair 306 having a first resistor R₁ 308 and a first capacitor C₁ 310 connected in parallel, and one or more such additional RC pairs 312. As such, conventional ECM 300 is an n-RC ECM where n≥2.

Voltage source 302 represents the open-circuit voltage (OCV) of the traction battery 124. The OCV of the traction battery 124 depends on the state-of-charge (SOC) and the temperature of the traction battery 124. Resistor R₀ 304 represents an internal resistance of the traction battery 124. The RC pairs represent the diffusion process of the traction battery 124. As such, the diffusion process of the traction battery 124 in conventional ECM 300 may be described with RC pairs R₁ and C₁, . . . , Rₙ and Cₙ.

Voltage V₀ 314 is the voltage drop across resistor R₀ 304 due to battery current I 316 which flows across resistor R₀ 304. Voltage V₁ 318 is the voltage drop across first RC pair 306 due to battery current IR₁ which flows across resistor R₁ 308. A voltage drop is across each additional RC pair 312. Voltage Vₜ 320 is the voltage across the terminals of the traction battery 124 (i.e., the terminal voltage).

Parameters of the ECM 300 may include the resistors (i.e., resistor R₀, resistor R₁, and resistor Rₙ) and the capacitors (i.e., capacitor C₁ and capacitor Cₙ). The parameters are to have values whereby the calculated output of the ECM 300 in response to a hypothetical given input is representative of the actual output of the traction battery 124 in response to the actual given input. The values of the parameters can be learned online or locally by BECM 125 such as with an EKF.

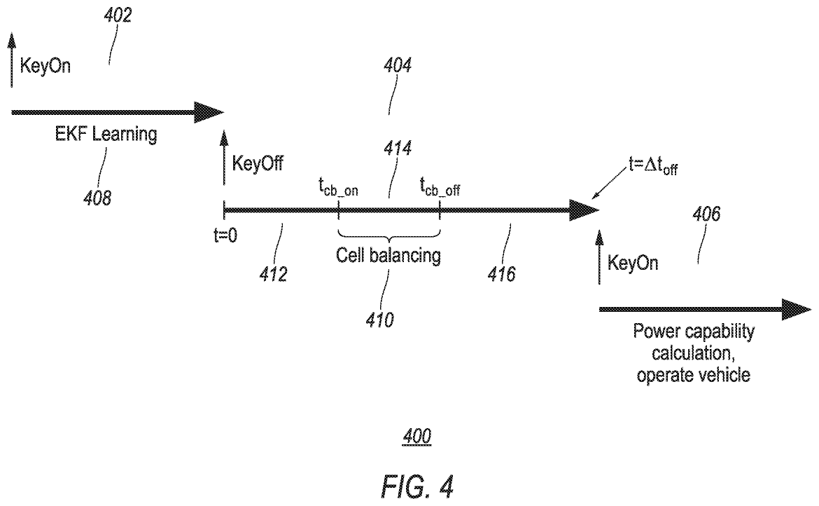

Referring to FIG. 4, an example timing graph of a process 400 for estimating the power capability of the traction battery of one embodiment of the present disclosure is illustrated. With continuing reference to FIGS. 1 to 3, the timeline of the process 400 may be generally divided into a first key on period 402 in which the vehicle 112 is in the operating status, a key off period 404 in which the vehicle 112 is parked, and a second key on period 406 in which the vehicle 112 is restarted to operate. The process 400 may be used to determine a power capability immediately or shortly after detecting the key on signal which starts the second key on period 406.

During the first key on period 402, the vehicle 112 is in the operating status with the traction battery 124 supplying electric power to the electric machine 114 for propulsion. As discussed above, extended Kalman filter (EKF) learning process 408 may be performed by the BECM and/or the system controller 150 during the entire or a part of the first key on period 402. In the present example, a 4 RC Equivalent Circuit Model (ECM) (not shown) may be used to represent the battery cell model. The SOC of the traction battery 124 may be dynamically calculated as

$${SOC}_{k + 1} = {SOC}_{k} - \frac{Δ t}{3600 Q} {I}_{k}$$

wherein Δt denotes the time elapsed from an instant k, Iₖ denotes the battery current at the instant k, and Q denotes the total capacity of the traction battery 124. Since the 4 RC ECM is used in the present example, the voltage across each of the four RC pairs may be calculated using the following equations:

$${V}_{1 , k + 1} = ( 1 - \frac{Δ t}{{τ}_{1}} ) {V}_{1 , k} + \frac{Δ t}{{C}_{1}} {I}_{k}$$

$${V}_{2 , k + 1} = ( 1 - \frac{Δ t}{{τ}_{2}} ) {V}_{2 , k} + \frac{Δ t}{{C}_{2}} {I}_{k}$$

$${V}_{3 , k + 1} = ( 1 - \frac{Δ t}{{τ}_{3}} ) {V}_{3 , k} + \frac{Δ t}{{C}_{3}} {I}_{k}$$

$${V}_{4 , k + 1} = ( 1 - \frac{Δ t}{{τ}_{4}} ) {V}_{4 , k} + \frac{Δ t}{{C}_{4}} {I}_{k}$$

wherein τ₁, τ₂, τ₃ and τ₄ denote time constants associated with each respective RC pair.

Therefore, an output voltage of the EKF learning process 408 may be calculated as follows:

$${V}_{t , k} = {OCV ( SOC )}_{k} - {R}_{0 , k} {I}_{k} - {V}_{1 , k} - {V}_{2 , k} - {V}_{3 , k} - {V}_{4 , k}$$

In addition, the state vector (x) of the EKF 408 may be represented as

$$[ \begin{matrix}SOC & {R}_{0} & {V}_{1} & \frac{1}{C 1} & {V}_{2} & {V}_{3} & {V}_{4}\end{matrix} ]$$

The EKF 408 matrices may be represented as

$$\hat{A} = [ \begin{matrix}1 & & & & & & \\ & 1 & & & & & \\ & & 1 - Δ t / {τ}_{1} & Δ t I & & & \\ & & & 1 & & & \\ & & & 1 / ( γ * {τ}_{1 , k} ) Δ t I & 1 - Δ t / {τ}_{2} & & \\ & & & 1 / ( α * γ * {τ}_{1 , k} ) Δ t I & & 1 - Δ t / {τ}_{3} & \\ & & & 1 / ( {α}^{2} * γ * {τ}_{1 , k} ) Δ t I & & & 1 - Δ t / {τ}_{4}\end{matrix} ]$$

$$\hat{H} = [ \begin{matrix}\frac{\partial OCV}{\partial SOC} & - I & - 1 & 0 & - 1 & - 1 & - 1\end{matrix} ]$$

wherein the time constants τ may be calculated as functions of τ_{1,k}:

$${τ}_{2} = γ * {τ}_{1 , k}^{2}$$

$${τ}_{3} = α * γ * {τ}_{1 , k}^{2}$$

$${τ}_{4} = {α}^{2} * γ * {τ}_{1 , k}^{2}$$

From the above equations, it can be seen that the time constant τ of a succussing RC pair is long than the time constant τ of a predecessor RC pair. As an example, the time constant of the first RC pair ti may be 7 seconds. In this case, the time constant of the second RC pair τ₂ may be calculated as being equal to approximately 49 seconds, the time constant of the third RC pair τ₃ may be calculated as being equal to approximately 196 seconds, and the time constant of the fourth RC pair τ₄ may be calculated as being equal to approximately 784 seconds.

The voltage EKF estimated by the EKF process 408 may be compared with an actual measured voltage and corrections to the states and parameters may be made based on the comparison result.

As the vehicle 112 parks and switches off at to, the process 400 enters the key off period 404 and the main contactor 127 opens, separating the traction battery 124 from the rest of the vehicle 112. The key off period 404 starts at to which is used as a reference point and ends at to +Δt_{off}. Therefore, the key off period 404 lasts for a duration of Δt_{off}. In the present disclosure, a cell balancing process 410 may be performed during the key off period 404. Through the operation at the first key on period 402 (as well as other prior battery cycles), the cells 202 of the traction battery 124 may be at a slightly different SOC and have variation in capacity compared with each other. The cell balancing process 410 may redistribute electric charges among the cells 202 such that the SOC of each cell 202 is the same across all cells 202 of the traction battery 124. Although the cell balancing process 410 may be applied throughout the entire key on and off periods 402 and 404, in the present disclosure, the cell balancing process 410 is applied to only a part of the key off period. More specifically, the cell balancing process 410 starts at t_{cb_on} after to and ends at t_{cb_off} before t₀+Δt_{off}. Therefore, the key off period 404 may be further divided into a pre-balancing period 412, a cell balancing period 414, and a post-balancing period 416.

At the pre-balancing period 412, the SOC of the traction battery 124 may be calculated as follows:

$$SOC ( t ) = S O C ( 0 ) = S O C ( {t}_{o f f} )$$

wherein the SOC (t_{off}) denotes the state of charge of the traction battery 124 at the key off moment. The voltage of each of the battery cells 202 may be calculated as

$${V}_{i} ( t ) = {V}_{i} ( 0 ) * {e}^{\frac{- t}{{τ}_{i}}}$$

During the pre-balancing period, the total SOC of the traction battery 124 does not change and cell temperature is assumed to remain substantially the same as key off moment to. Therefore, the mapped parameter data may be determined using the cell temperature in an open-loop manner without using voltage feedback.

During the balancing period 414, the battery SOC may be calculated as follows:

$$SOC ( t ) = S O C ( 0 ) - ( {t}_{cb \_ off} - {t}_{cb \_ on} ) * {I}_{c b} / Q$$

wherein the I_{cb} denotes the current between cells as incurred by the cell balancing process 410, and Q denotes the capacity of the battery cell 202. As the cell balancing current I_{cb} is relatively small for the passive cell balancing circuit, the impact on the battery voltage and cell voltage of cell balancing current I_{cb} may be ignored. Therefore, the main factor for the battery cell voltage remains the time passed during the cell balancing process 410 calculated as follows:

$${V}_{i} ( {t}_{cb \_ off} ) = {V}_{i} ( 0 ) * {e}^{\frac{- {t}_{cb \_ off}}{{τ}_{i}}}$$

Since the cell balancing is performed internally between cells 202 within the traction battery 124, the total SOC of the traction battery 124 remains the same. Similarly, the mapped parameter data may be determined using the cell temperature in an open-loop manner without using voltage feedback.

The cell balancing process 410 completes at t_{cb_off} which is before the next key on signal is received. During the post-balancing period 416 The SOC of the battery 124 remains unchanged as no current occurs:

SOC(t_{off})=SOC(t_{cb_off})

However, the voltage of each cell may decay based on the respective time constants as follows:

$${V}_{i} ( {t}_{off} ) = {V}_{i} ( 0 ) * {e}^{\frac{- {t}_{off}}{{τ}_{i}}}$$

The parameters calculated during the key off period 404 may be used to determine the power capability immediately or shortly after the next key on signal is received. In the present example, the key on signal is received at t₀+Δt_{off} and the BECM 125 as well as other components of the vehicle 112 power up to determine a power capability of the traction battery 124.

BECM 125 activates vehicle sensors 210, 208, 204 to measure battery parameters such as battery temperature T, voltage V and current I. An open circuit voltage (OCV) of the traction battery 124 may be estimated as a function of the battery temperature T and the SOC which is dynamically determined during the key off period 404.

With the proposed 4 RC ECM, the BECM 125 may derive the battery current limit for discharge as

$$i = \frac{OCV - {V}_{t} - {V}_{1} ( 0 ) {e}^{- \frac{t}{{τ}_{1}}} - {V}_{2} ( 0 ) {e}^{- \frac{t}{{τ}_{2}}} - {V}_{3} ( 0 ) {e}^{- \frac{t}{{τ}_{3}}} … - {V}_{n} ( 0 ) {e}^{- \frac{t}{{τ}_{n}}}}{{R}_{0} + {R}_{1} ( 1 - {e}^{- \frac{t}{{τ}_{1}}} ) + {R}_{2} ( 1 - {e}^{\frac{t}{{τ}_{2}}} ) + … {R}_{n} ( 1 - {e}^{- \frac{t}{{τ}_{n}}} )}$$

wherein Vₜ is the battery terminal voltage, V₁(0), V₂(0), . . . . Vn(0) are the voltages across each respective pair at time t=0 or at the moment when power estimation is updated. τ₂, τ₃, . . . τ₃ are functions of τ₁, and R₂, R₃, . . . . Rₙ are functions of R₁.

During the discharge case (with the assumption that the discharge current is positive), BECM 125 determines the discharge current limit by

$${i}_{max} = \frac{\begin{matrix}OCV - {V}_{t \_ min} - {V}_{1} ( 0 ) {e}^{- \frac{t}{{τ}_{1}}} - \\ {V}_{2} ( 0 ) {e}^{- \frac{t}{{τ}_{2}}} - {V}_{3} ( 0 ) {e}^{- \frac{t}{{τ}_{3}}} … - {V}_{n} ( 0 ) {e}^{- \frac{t}{{τ}_{n}}}\end{matrix}}{{R}_{0} + {R}_{1} ( 1 - {e}^{- \frac{t}{{τ}_{1}}} ) + {R}_{2} ( 1 - {e}^{- \frac{t}{{τ}_{2}}} ) + … {R}_{n} ( 1 - {e}^{- \frac{t}{{τ}_{n}}} )}$$

wherein Vₜₘᵢₙ is the traction battery minimum voltage limit. The traction battery minimum voltage limit Vₘᵢₙ may be determined in various manners. For instance, The minimum voltage limit Vₘᵢₙ may be the highest of: 1) the minimum voltage that every component (e.g. electric drive, DC/DC converter, heater, etc.) can operate at, or 2) the lowest voltage the battery pack can safely operate at (and maintain life, etc.). As an example, the lowest voltage the battery pack can safely operate may be the minimum cell voltage multiplied by the number of cells in series, or an average/medium voltage of the cells 202 multiplied by the number of cells. In some examples, batteries can operate at a lower voltage at cold temperatures than at room temperature. These system limits (e.g. the traction battery minimum voltage limit Vₘᵢₙ) may be defined during development of a vehicle.

In view of the above, the voltage under the maximum discharge current will be

$${V}_{t} d is = OCV - [ {V}_{1} ( 0 ) {e}^{- \frac{t}{{τ}_{1}}} + {V}_{2} ( 0 ) {e}^{- \frac{t}{{τ}_{2}}} + {V}_{3} ( 0 ) {e}^{- \frac{t}{{τ}_{3}}} … + {V}_{n} ( 0 ) {e}^{- \frac{t}{{τ}_{n}}} ] - {i}_{max} [ {R}_{1} ( 1 - {e}^{- \frac{t}{{τ}_{1}}} ) + {R}_{2} ( 1 - {e}^{- \frac{t}{{τ}_{2}}} ) + … {R}_{n} ( 1 - {e}^{- \frac{t}{{τ}_{n}}} ) ]$$

In general, battery system may be associated with various limitations. As a few non-limiting examples, the limitations may include the minimum battery voltage Vₘᵢₙ, the maximum current iₘₐₓ, and a minimum cell voltage V_{cell_min}. The power capability should be calculated under the condition that all of these limitations are met. For example, if the battery 124 is voltage limited (e.g. Vₘᵢₙ_applies), the power capability may be the battery pack voltage multiplied by the current required to reach that battery pack voltage. Alternatively, if the battery 124 is current limited, the power capability may be the maximum current multiplied by the voltage the battery would encounter at that maximum current. Alternatively, if the battery 124 is cell voltage limited, the power capability may be the current required to get to that minimum cell voltage multiplied by the voltage of every cell at the corresponding current.

Therefore, the discharge power capability at time t seconds later will be

$${P}_{cap \_ dis} ( t ) = \{ \begin{matrix}{i}_{max} * {V}_{min} & if i\_max < {i}_{dis \_ limit} \\ {i}_{dis \_ limit} * {V}_{t \_ dis} & Otherwise\end{matrix}$$

Rather than using the current value iₘₐₓ without further examination, examples of the present disclosure compare iₘₐₓ to a discharge limit current i_{dis_limit} to determine if iₘₐₓ is less than or equal to i_{dis_limit}. The reason for this is that the discharge limit current i_{dis_limit} may provide a boundary that is lower than iₘₐₓ.

With the discharge power capability determined, the system controller 150 and/or the BECM 125 may operate the discharge of the traction battery 124 using the power capability. For instance, responsive to detecting a power demand for propulsion from the electric machine 114 greater than the power capability of the traction battery 124, the system controller 150 and/or the BECM 125 may limit the power output from the traction battery 124 using the power capability.

It is noted that although the process 400 as described above is directed to determining the power capability of the entire traction battery 124, the present disclosure is not limited thereto. The process 400 may also be applied to determining the power capability of each individual battery cell 202. The equations used to calculate the voltage, current, SOC or the like of the traction battery 124 may be used to calculate the same parameters of the individual battery cells 202 under essentially the same principle.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, case of assembly, etc. As such, embodiments described as less desirable than other embodiments or prior art implementations with respect to one or more characteristics are not outside the scope of the disclosure and may be desirable for particular applications.

What is claimed is:

1. A power system for a vehicle, comprising:
one or more controllers programmed to, after activation of the vehicle, charge and discharge a traction battery according to power limits that are based on polarization voltages describing internal states of the traction battery and that are a function of polarization voltages present at a last deactivation of the vehicle and decay values having time constants that are based on a state of charge of the traction battery and a temperature associated with the traction battery.

2. The power system of claim 1, wherein the decay values are exponential decay values.

3. The power system of claim 1, wherein the polarization voltages are further a function of a duration of time between the last deactivation of the vehicle and the activation of the vehicle.

4. The power system of claim 3, wherein the polarization voltages are further a function of start and stop times of cell balancing during the duration of time.

5. The power system of claim 1, wherein the temperature is a temperature of the traction battery at the last deactivation of the vehicle.

6. The power system of claim 1, wherein the temperature is an average of temperatures of the traction battery at the last deactivation of the vehicle and the activation of the vehicle.

7. The power system of claim 1, wherein the state of charge is a state of charge of the traction battery at the last deactivation of the vehicle.

8. A method comprising:
after activation of a vehicle, charging and discharging a traction battery of the vehicle according to power limits that are based on polarization voltages describing internal states of the traction battery and that are a function of polarization voltages present at a last deactivation of the vehicle and decay values having time constants that are based on a state of charge of the traction battery and a temperature associated with the traction battery.

9. The method of claim 8, wherein the decay values are exponential decay values.

10. The method of claim 8, wherein the polarization voltages are further a function of a duration of time between the last deactivation of the vehicle and activation of the vehicle.

11. The method of claim 10, wherein the polarization voltages are further a function of start and stop times of cell balancing during the duration of time.

12. The method of claim 8, wherein the temperature is a temperature of the traction battery at the last deactivation of the vehicle.

13. The method of claim 8, wherein the temperature is an average of temperatures of the traction battery at the last deactivation of the vehicle and the activation of the vehicle.

14. The method of claim 8, wherein the state of charge is a state of charge of the traction battery at the last deactivation of the vehicle.

15. A vehicle comprising:
a traction battery; and
one or more controllers programmed to, after activation of the vehicle, charge and discharge the traction battery according to power limits, wherein the power limits are derived from polarization voltages that are based on decay values having time constants that are based on a state of charge of the traction battery and a temperature associated with the traction battery.

16. The vehicle of claim 15, wherein the decay values are exponential decay values.

17. The vehicle of claim 15, wherein the polarization voltages are further derived from a duration of time between a last deactivation of the vehicle and the activation of the vehicle.

18. The vehicle of claim 17, wherein the polarization voltages are further derived from start and stop times of cell balancing during the duration of time.
